(19) United States
(12) Patent Application Publication
(10) Pub. No.: US 2016/0240416 A1
(43) Pub. Date: Aug. 18, 2016

(54) DEVICE AND METHOD FOR CONVEYING AND FLIPPING A COMPONENT

(71) Applicant: EXIS TECH SDN BHD, NEGERI SEMBILAN (MY)

(72) Inventor: HENG LEE LEE, NEGERI SEMBILAN (MY)

(21) Appl. No.: 14/737,891

(22) Filed: Jun. 12, 2015

(30) Foreign Application Priority Data
Feb. 16, 2015 (MY) PI 2015700477

(51) Int. Cl. H01L 21/677; H01L 21/67; H01L 21/68; B65G 47/248

(52) U.S. Cl. CPC H01L 21/67718; B65G 47/248; H01L 21/67706; H01L 21/67259; H01L 21/68

(57) ABSTRACT

The present invention relates to a device (1) and method for conveying and flipping a component (10) for use in conjunction with a rotary turret module (30). The device (1) includes at least a pair of spaced apart flipping arms, a first and second flipping arms (100 and 300) mounted on a platform (500). Each of the flipping arms (100, 300) is provided with one nozzle (110, 310) having one end (111) configured to pick the component (10) and another end (311) fixedly mounted on a shaft (130, 330) supported on the flipping arm (100, 300) and is operatively connected to a rotary actuating means (150, 350). The rotary actuating means (150, 350) is adapted to be capable of affecting a rotational motion of the shaft (130, 330), thereby rotating the nozzles (110, 310) in a counter direction by substantially 90 degrees. The device is also provided with a linear actuating means (400) suitably mounted on the platform (500). The linear actuating means (400) is operatively connected to at least one of to the flipping arms (100, 300 or 100 and 300) and is adapted to be capable of moving the flipping arm (100, 300) or arms (100 and 300) in a horizontal direction so as to position the nozzles (110, 310) substantially proximate to each other for transferring of the component (10) between the nozzles (110, 310) and thereby, flipping the component (10) at 180 degrees.

### FIELD OF INVENTION

The present invention relates to a device and method for conveying and flipping a component, and more particularly to a device and method for conveying and flipping a semiconductor component for use in conjunction with a rotary turret module in semiconductor industry.

### BACKGROUND OF INVENTION

Semiconductor processing can be divided into two sequential sub-processes generally referred to as front-end and back-end processes. Rotary turret module is widely used in the back-end processes such as testing, inspection and packaging of the semiconductor components due to its high throughput rates.

During processing of the semiconductor components, orientation of the semiconductor components may need to be changed according to the various conditions or requirements in the back-end processes. For example, some of the semiconductor components are required to change from “live-bug” position to “dead-bug” position or vice versa before testing or inspection can be carried out. It should be noted that the desired orientation of the semiconductor components can be changed by flipping or inverting the component 180 degrees. The existing flipping module used in the industry involves complex procedures and thus could affect the progress of the entire back-end processes as more time is spent in changing or inverting the orientation of the semiconductor components to the desired orientation.

Therefore, it is desirous to provide a device that is configured to flexibly use in conjunction with a rotary turret module and is capable of carrying out simple yet efficient process to change the orientation of the semiconductor components for further processing.

### SUMMARY OF THE INVENTION

The present invention relates to a device for conveying and flipping a component for use in conjunction with a rotary turret module. In the preferred embodiment, the device includes at least a pair of spaced apart flipping arms, a first flipping arm and a second flipping arm suitably mounted on a platform. It should be noted that the flipping arms are preferably positioned adjacent to one another.

Each of the flipping arms is provided with one nozzle, wherein a first nozzle is associated with the first flipping arm and a second nozzle is associated with the second flipping arm. Each of the first and second nozzles has one end configured to pick a component from a pick-up head of the rotary turret module and another end fixedly mounted on a shaft with a longitudinal axis of the nozzle substantially orthogonal to a longitudinal axis of the shaft. In accordance with the preferred embodiment of the present invention, the shaft is supported on the flipping arm and is operatively connected to a rotary actuating means. The rotary actuating means is adapted to be capable of affecting a rotational motion of the shaft about the longitudinal axis of the shaft, thereby rotating the nozzles by substantially 90 degrees. It should be noted the nozzles are rotated in a counter direction so as to position the ends of the nozzles to pick the component to face each other. Preferably, the device is provided with a pneumatic means to control the pressure of the nozzle either to hold or to release the component.

Preferably, the device is provided with a linear actuating means suitably mounted on the platform. It should be noted that the linear actuating means is operatively connected to at least one of to the flipping arms. The linear actuating means is adapted to be capable of moving the flipping arm or arms in a horizontal direction.

In one embodiment of the present invention, the linear actuating means is operatively connected to the first flipping arm. In this embodiment, the first flipping arm is moving horizontally towards or apart from the second flipping arm. In another embodiment, the linear actuating means is operatively connected to the second flipping arm. In this embodiment, the second flipping arm is moving horizontally towards or apart from the first flipping arm. In yet another embodiment of the present invention, the linear actuating means is operatively connected to the first and second flipping arms. In this embodiment, the flipping arms are capable of moving towards or apart from one another.

It should be noted that the linear actuating means of each of the three embodiments above is provided with a sensor and/or an encoder. The sensor and/or the encoder is adapted to control and determine the distance travelled by the moving flipping arm or arms so as to position the ends of the nozzles configured to pick the component proximate to each other, thereby allowing the transfer of the component from the first nozzle to the second nozzle. It will be appreciated that the component is flipped 180 degrees when the component is transferred from the first nozzle to the second nozzle.

The present invention consists of several novel features and a combination of parts hereinafter fully described and illustrated in the accompanying description and drawing, it being understood that various changes in the details may be made without departing from the scope of the invention or sacrificing any of the advantages of the present invention.

### BRIEF DESCRIPTION OF THE DRAWINGS

The present invention will be fully understood from the detailed description given herein below and the accompanying drawing which is given by way of illustration only, and thus is not limitative of the present invention, wherein:

FIG. 1 illustrates the perspective view of a device for conveying and flipping a component for use in conjunction with a rotary turret module;

FIG. 2 shows the back view of the device with a first nozzle holds the component picked from a pick-up head of the rotary turret module;

FIG. 3 shows the back view of the device with the nozzles of a first and second flipping arms rotated to substantially 90 degrees; and

FIG. 4 illustrates the back view of the device with the second nozzle holds the 180 degrees flipped component.

### DETAILED DESCRIPTION OF THE PREFERRED EMBODIMENTS

The present invention relates to a device for conveying and flipping a component for use in conjunction with a rotary turret module. Hereinafter, this specification will describe the present invention according to preferred embodiments. However, it is to be understood that limiting the description to the preferred embodiments of the invention is merely to facilitate discussion of the present invention and it is envisioned that those skilled in the art may devise various modifications and equivalents without departing from the scope of the appended claims.

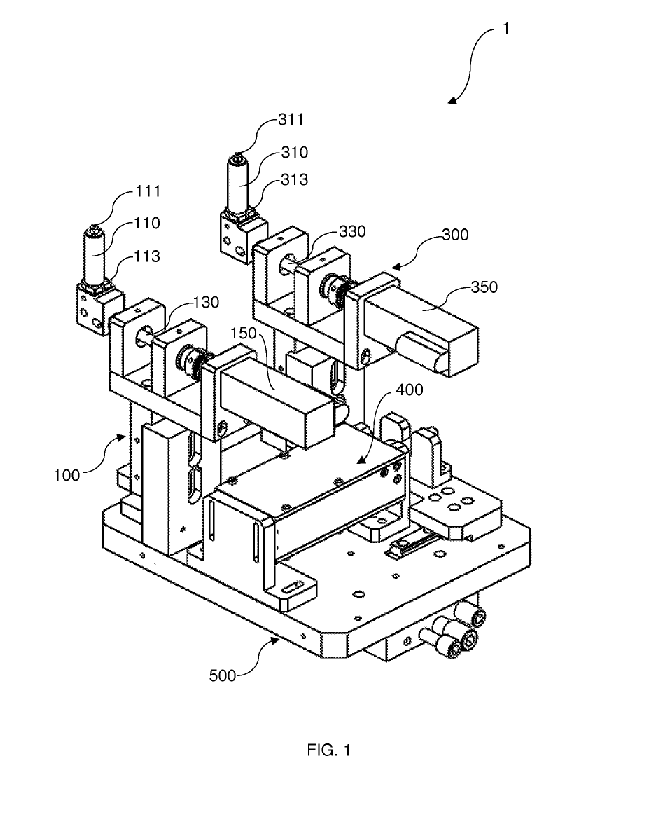

The device for conveying and flipping a component for use in conjunction with a rotary turret module according to the preferred mode of carrying out the present invention will now be described in accordance to the accompanying drawings FIGS. 1 to 4, either individually or in any combination thereof.

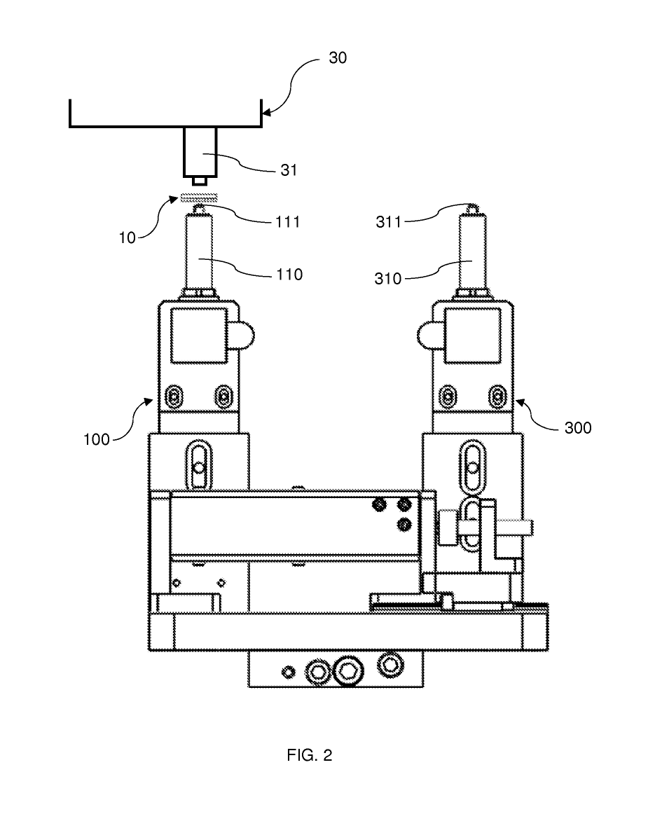

Referring to FIGS. 1 and 2, illustrated therein is a device 1 for conveying and flipping a component 10 according to the preferred embodiment of the present invention. The device 1 includes at least a pair of spaced apart flipping arms, a first flipping arm 100 and a second flipping arm 300. The flipping arms 100 and 300 are preferably positioned adjacent to one another and suitably mounted on a platform 500. It should be noted that each of the flipping arms 100, 300 is provided with a nozzle, a first nozzle 110 and a second nozzle 310, wherein the first nozzle 110 is associated with the first flipping arm 100 and the second nozzle 310 is associated with the second flipping arm 300.

In the preferred embodiment of the present invention, each of the nozzles 110, 310 is having one end 111, 311 configured to pick the component 10 preferably from a pick-up head 31 of a rotary turret module 30 and another end 113, 313 fixedly mounted on a shaft 130, 330 with a longitudinal axis of the nozzle 110, 310 substantially orthogonal to a longitudinal axis of the shaft 130, 330. It should be noted that the component 10 can include but not limited to semiconductor die or chip. In the preferred embodiment, each of the shafts 130, 330 is supported on the flipping arm 100, 300 and is operatively connected to a rotary actuating means 150, 350. By way of example but not limitation, the rotary actuating means 150, 350 is of the voice coil type or the like.

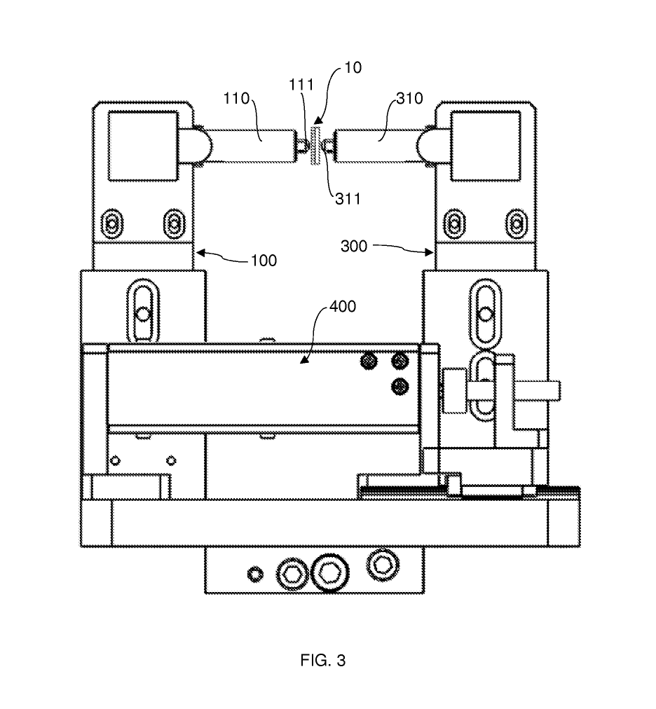

The rotary actuating means 150 and 350 in accordance with the preferred embodiment of the present invention is adapted to be capable of affecting a rotational motion of the shafts 130 and 330 about the longitudinal axis of the shaft 130, 330 so as to rotate the nozzles 110 and 310 by substantially 90 degrees. It should be noted that the first nozzle 110 and the second nozzle 310 are rotated in a counter direction so as to position the end 111 of the first nozzle 110 and the end 311 of the second nozzle 310 to face each other as illustrated in FIG. 3. In accordance with the preferred embodiment of the present invention, the device 1 is provided with a pneumatic means (not shown) to control the pressure of the nozzles 110 and 310 so as to enable the nozzles 110 and 310 either to hold or to release the component 10. It should be noted that the pneumatic means can include but not limited to pressure regulators or vacuum pump.

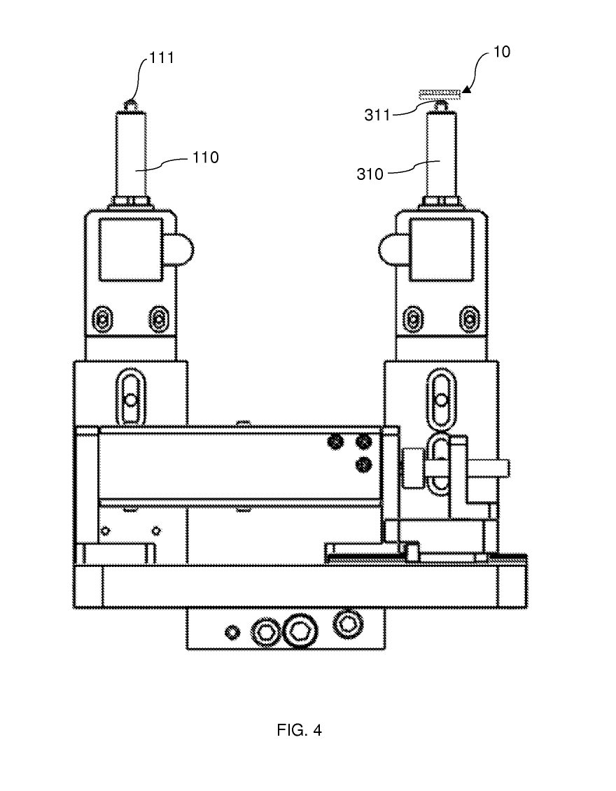

The device 1 is provided with a linear actuating means 400. The linear actuating means 400 is suitably mounted on the platform 500 and operatively connected to at least one of the flipping arms 100, 300. The linear actuating means 400 is adapted to be capable of moving the flipping arm 100, 300 or arms 100 and 300 in a horizontal direction so as to bring the nozzles 110, 310 towards or apart from one another. The linear actuating means 400 is provided with a sensor and/or an encoder (not shown). It should be noted that the sensor and/or encoder is adapted to control and determine the distance travelled by the moving flipping arm 100, 300 or arms 100 and 300. The ends 111 and 311 of the nozzles 110 and 310 configured to pick-up the component 10 are brought into close proximity with each other during transferring of the component 10 from the first nozzle 110 to the second nozzle 310. Once the component 10 is transferred to the second nozzle 310, the linear actuating means 400 is operable to return the flipping arm 100, 300 or arms 100 and 300 to the respective original position. The rotary actuating means 150 and 350 then rotate the shafts 130 and 330 about the longitudinal axis of the shafts 130 and 330 to return the nozzles 110 and 310 to the respective original position. In this way, the component 10 held on the second nozzle 310 would have been flipped by 180 degrees while the first nozzle 110 is ready to receive another component to be flipped as illustrated in FIG. 4.

In one embodiment, the linear actuating means 400 is operatively connected to the first flipping arm 100, thereby effecting the horizontal movement of the first flipping arm 100 towards or apart from the second flipping arm 300. In another embodiment, the linear actuating means 400 is operatively connected to the second flipping arm 300. In this embodiment, the second flipping arm 300 is moving horizontally towards or apart from the first flipping arm 100. In yet another embodiment, the liner actuating means is operatively connected to the first and second flipping arms 100 and 300, thereby effecting the horizontal movements of the first and second flipping arms 100 and 300 towards or apart from one another. By way of example but not limitation, the linear actuating means 400 is of the voice coil type or the like.

The present invention also relates to a method for conveying and flipping a component 10 for use in conjunction with a rotary turret module 30 according to the device 1 described above wherein the method includes steps of:
a. connecting a first nozzle 110 associated with a first flipping arm 100 with a source of negative pressure;
b. picking a component 10 preferably from a pick-up head 31 of a rotary turret module 30 with the first nozzle 110;
c. rotating the first nozzle 110 and a second nozzle 310 associated with a second flipping arm 300 by substantially 90 degrees in a counter direction so as to position the nozzles 110 and 310 to face each other;
d. moving at least one of the flipping arms 100, 300 or 100 and 300 in a horizontal direction, thereby bringing the nozzles 110 and 310 to close proximity to each other;
e. connecting the negative pressure to the second nozzle 310;
f. neutralising the negative pressure at the first nozzle 110, thereby transferring the component 10 from the first nozzle 110 to the second nozzle 310;
g. moving the flipping arms 100 and 300 apart in the horizontal direction;
h. moving the first and second nozzles 110 and 310 to a vertically upward position, thereby flipping the component 10 180 degrees; and
i. repeating steps a to h for picking and flipping a second component.

The method also includes step of providing a rotary actuating means 150, 350 operatively connected to a shaft 130, 330 supported on the flipping arm 100, 300. It should be noted that one end 111, 311 of the nozzles 110, 310 of the flipping arms 100, 300 is configured to pick the component 10 and another end 113, 313 is fixedly mounted on the shaft 130, 330 with a longitudinal axis of the nozzle 110, 310 substantially orthogonal to a longitudinal axis of the shaft 130, 330. The rotary actuating means 150, 350 is adapted to be capable of effecting a rotational motion of the shaft 130, 330 about the longitudinal axis of the shaft 130, 330 and hence the nozzles 110, 310 in a counter direction.

In the preferred embodiment, the method further includes step of providing a pneumatic means to control the pressure of the nozzles 110, 310 so as to enable the nozzles 110, 310 to either hold or release the component 10. It should be noted that the method in accordance with the preferred embodiment of the present invention also includes step of providing a linear actuating means 400 operatively connected to at least one of the flipping arms 100, 300 or 100 and 300. In the preferred embodiment, the linear actuating means 400 is suitably mounted on a platform 500.

The linear actuating means 400 is configured to effect a horizontal motion of the flipping arm 100, 300 or arms 100 and 300 so as to position the nozzles 110, 310 sufficiently proximate to each other for transferring of the component 10 between the first and second nozzle 110 and 310. In one embodiment, the first flipping arm 100 is adapted to move horizontally towards or apart from the second flipping arm 300. In another embodiment, the second flipping arm 300 is adapted to move towards or apart from the first flipping arm 100. In yet another embodiment, the first and second flipping arms 100 and 300 are adapted to move horizontally towards or apart from one another. The linear actuating means 400 is provided with a sensor and/or an encoder to determine and control the distance travelled by the flipping arm 100, 300 or arms 100 and 300.

Once the component 10 has been transferred to the second nozzle 310, the flipping arms 100 and 300 moved apart and followed by rotations of the first and second nozzles 110 and 310 back to their respective original positions. The component 10, held in the second nozzle 310 would have been flipped 180 degrees and ready to be picked by a pick-up head 31 of the rotary turret module 30 for further processing while the first nozzle is ready to receive another component 10.

The invention being thus described, it is obvious that the same may be varied in many ways. Such variations are not to be regarded as a departure from the principle and scope of the invention, and all such modifications as would be obvious to one skilled in the art intended to be included within the scope of following claims.

1. A device (1) for conveying and flipping a component (10) for use in conjunction with a rotary turret module (30), the device (1) includes
at least a pair of spaced apart flipping arms (100, 300), a first flipping arm (100) and a second flipping arm (300), mounted on a platform (500); wherein each of the flipping arms (100, 300) is provided with one nozzle, a first nozzle (110) associated with the first flipping arm (100) and a second nozzle (310) associated with the second flipping arm (300), each having one end (111, 311) configured to pick the component (10) and another end (113, 311) fixedly mounted on a shaft (130, 330) with a longitudinal axis of the nozzle (110, 310) substantially orthogonal to a longitudinal axis of the shaft (130, 330); the shaft (130, 330) being supported on the flipping arm (100, 300) and operatively connected to a rotary actuating means (150, 350); wherein the rotary actuating means (150, 350) is adapted to be capable of effecting a rotational motion of the shaft (130, 330) about the longitudinal axis of the shaft (130, 330) and hence the nozzles (110, 310) by substantially 90 degrees,
wherein the nozzles (110, 310) are caused to rotate in a counter direction so as to position the ends (111, 311) of the nozzles (110, 310) configured to pick the component (10) to face each other;
a pneumatic means (not shown) for controlling the pressure at the nozzles (110, 310) to enable the nozzles (110, 310) either to hold or to release the component (10); and
a linear actuating means (400) mounted on the platform (500) and operatively connected to at least one of to the flipping arms (100, 300 or 100 and 300), the linear actuating means (400) being adapted to be capable of moving at least one of the flipping arms (100, 300 or 100 and 300) in a horizontal direction to bring the nozzles (110, 310) towards or apart from one another.

2. The device (1) for conveying and flipping a component (10) according to claim 1, wherein the two flipping arms (100 and 300) are preferably positioned adjacent to one another.

3. The device (1) for conveying and flipping a component (10) according to claim 1, wherein the first flipping arm (100) is moving horizontally towards or apart from the second flipping arm (300).

4. The device (1) for conveying and flipping a component (10) according to claim 1, wherein the second flipping arm (300) is moving horizontally towards or apart from the first flipping arm (100).

5. The device (1) for conveying and flipping a component (10) according to claim 1, wherein the first and second flipping arms (100 and 300) are moving horizontally towards or apart from each other.

6. The device (1) for conveying and flipping a component (10) according to claim 1, wherein the linear actuating means (400) is provided with a sensor and/or an encoder (not shown).

7. The device (1) for conveying and flipping a component (10) according to claim 6, wherein the sensor and/or the encoder (not shown) determines the distance travelled by the moving flipping arm (100, 300) or arms (100 and 300) so as to bring the ends (111, 311) of the nozzles (110, 310) configured to pick the component (100 to close proximity to each other to effect transfer of the component (10) from the first nozzle (110) to the second nozzle (310).

8. A method for conveying and flipping a component (10) for use in conjunction with a rotary turret module (30) according to the device (1) for conveying and flipping a component (10) comprising the steps of
a. connecting a first nozzle (110) associated with a first flipping arm (100) with a source of negative pressure;
b. picking a component (100) with the first nozzle (110);
c. rotating the first nozzle (110) and a second nozzle (330) associated with a second flipping arm (300) by substantially 90 degrees in a counter direction so as to position the nozzles (110 and 310) to face each other;
d. moving at least one of the flipping arms (100, 300 or 100 and 300) in a horizontal direction, thereby bringing the nozzles (110 and 310) to close proximity to each other;
e. connecting the negative pressure to the second nozzle (310);
f. neutralising the negative pressure at the first nozzle (110), thereby transferring the component (10) from the first nozzle (110) to the second nozzle (310);
g. moving the flipping arms (100 and 300) apart in the horizontal direction;
h. moving the first and second nozzles (110 and 310) to a vertically upward position, thereby flipping the component (10) 180 degrees; and
i. repeating steps a to h for picking and flipping a second component.

9. The method for conveying and flipping a component (10) according to claim 8, wherein the first nozzle (110) is preferably picked the component (10) from a pick-up head (31) of the rotary turret module (30) in step b.

10. The method for conveying and flipping a component (10) according to claim 8, wherein the 180 degrees flipped component (10) in step h is preferably picked by the pick-up head (31) of the rotary turret module (30).

11. The method for conveying and flipping a component (10) according to claim 8, wherein the nozzle (110, 310) having one end (111, 311) configured to pick the component (10) and another end (113, 313) fixedly mounted on a shaft (130, 330) supported on the flipping arm (100, 300).

12. The method for conveying and flipping a component (10) according to claim 8, wherein the shaft (113, 313) is operatively connected to a rotary actuating means (150, 350).

13. The method for conveying and flipping a component (10) according to claim 8, wherein the rotary actuating means (150, 350) is adapted to be capable of effecting a rotational motion of the shaft (113, 313) and hence the nozzles (110, 310) in a counter direction so as to position the ends (111, 311) of the nozzles (110, 310) configured to pick the component (10) to face each other.

14. The method for conveying and flipping a component (10) according to claim 8, wherein the pressure of the nozzles (110, 310) in steps a, e and f is controlled by a pneumatic means (not shown).

15. The method for conveying and flipping a component (10) according to claim 8, wherein the horizontal motion of the flipping arms (100, 300) in steps d and g are effected by a linear actuating means (400) operatively connected to at least one of the flipping arms (100, 300 or 100 and 300).

16. The method for conveying and flipping a component (10) according to claim 8, wherein the first flipping arm (100) is moving horizontally towards or apart from the second flipping arm (300).

17. The method for conveying and flipping a component (10) according to claim 8, wherein the second flipping arm (300) is moving horizontally towards or apart from the first flipping arm (100).

18. The method for conveying and flipping a component (10) according to claim 8, wherein the first and second flipping arms (100 and 300) are moving horizontally towards or apart from each other.

19. The method for conveying and flipping a component (10) according to claim 8, wherein the distance travelled by the moving flipping arm (100, 300) or arms (100 and 300) is determined by a sensor and/or an encoder (not shown).

20. The method for conveying and flipping a component (10) according to claim 12, wherein the rotary actuating means (150, 350) is adapted to be capable of effecting a rotational motion of the shaft (113, 313) and hence the nozzles (110, 310) in a counter direction so as to position the ends (111, 311) of the nozzles (110, 310) configured to pick the component (10) to face each other.

21. The method for conveying and flipping a component (10) according to claim 15, wherein the first flipping arm (100) is moving horizontally towards or apart from the second flipping arm (300).

22. The method for conveying and flipping a component (10) according to claim 15, wherein the second flipping arm (300) is moving horizontally towards or apart from the first flipping arm (100).

23. The method for conveying and flipping a component (10) according to claim 15, wherein the first and second flipping arms (100 and 300) are moving horizontally towards or apart from each other.

24. The method for conveying and flipping a component (10) according to claim 15, wherein the distance travelled by the moving flipping arm (100, 300) or arms (100 and 300) is determined by a sensor and/or an encoder (not shown).
